(19) United States
(12) Patent Application Publication
(10) Pub. No.: US 2021/0314798 A1
(43) Pub. Date: Oct. 7, 2021

(54) WIRELESS COMMUNICATION SYSTEM, INPUT-SIDE DEVICE, AND OUTPUT-SIDE DEVICE

(71) Applicant: HITACHI KOKUSAI ELECTRIC INC., Tokyo (JP)

(72) Inventors: Hiroki KATO, Tokyo (JP); Tatsuhiro NAKADA, Tokyo (JP); Daiki HOSHI, Tokyo (JP)

(21) Appl. No.: 17/271,617

(22) PCT Filed: Aug. 22, 2019
(86) PCT No.: PCT/JP2019/032830

§ 371 Date: Feb. 26, 2021

(30) Foreign Application Priority Data
Sep. 20, 2018 (JP) 2018-175547

(51) Int. Cl. H04W 24/08; H04L 12/861

(52) U.S. Cl. CPC H04W 24/08; H04L 49/90

(57) ABSTRACT

There is provided a wireless communication system in which it is possible to transmit data with low delay by suppressing an increase in buffer capacity, while preventing the depletion of data within each buffer. A base station uses a relationship in which the sum of an amount of data stored in a buffer of a mobile station and an amount of data stored in a buffer of a base station is constant to determine a video coding rate and a wireless transmission rate on the basis of quality of a wireless propagation path measured by a propagation path quality measurement unit and the data amount stored in the buffer of the base station, transmits the determined rates to the mobile station, and causes the determined rates to be reflected in the settings of a video encoding unit and a wireless encoding unit.

### TECHNICAL FIELD

The present invention relates to a wireless communication system that transmits data such as video data, audio data, or the like.

### BACKGROUND

Recently, demand for transmission of high-precision videos, such as a super high vision video, is increasing, and stable massive-capacity transmission with low delay is required even in a wireless communication system for mobile video transmission. However, a wireless propagation path is considerably changed in quality by multipath propagation, shadowing, or the like. Accordingly, in order to stably transmit videos all the time, it is necessary to run a wireless propagation path with a margin for the lowest quality thereof. Patent Document 1 discloses a technique for increasing a transmission rate by selecting an appropriate modulation scheme and coding rate even in a high antenna correlation environment or an environment in which a narrow-band interference signal is mixed.

### RELATED ART DOCUMENT

Patent Document 1: International Patent Application Publication No. 2016/186000

There is a wireless video transmission system that adaptively changes a wireless transmission rate and a video coding rate according to the quality of a mobile wireless propagation path, but there is a large difference in the frequency of changes between a wireless transmission rate and a video coding rate. In general, the wireless transmission rate may follow the quality of a wireless propagation path at relatively high speed, whereas the video coding rate has a low frequency of changes and cannot follow the quality of a wireless propagation path as fast as the wireless transmission rate.

Accordingly, a discrepancy occurs between the wireless transmission rate and the video coding rate. To compensate for the discrepancy, it is necessary to install a buffer on each of a transmission side of a video and a reception side of the video. However, when the quality of a wireless propagation path is drastically changed, a disparity between the wireless transmission rate and the video coding rate is increased, and it is likely that video stuttering or transmission efficiency degradation occurs due to the depletion of data in each buffer. When a video having a sufficient number of frames is accumulated in a buffer, it is possible to prevent the depletion of data, but a delay time of video transmission is increased, which is problematic.

### SUMMARY

The present invention has been proposed in view of the above situation and provides a wireless communication system in which it is possible to prevent an increase in buffer capacity and transmit data with low delay while preventing the depletion of data in each buffer.

In accordance with an aspect of the present invention, a wireless communication system is provided.

The wireless communication system includes an input-side device configured to encode data input thereto and wirelessly transmit the data, and an output-side device configured to decode the data received from the input-side device and output the data.

The input-side device includes an encoding unit configured to encode data input thereto according to a set coding rate, a transmission unit configured to wirelessly transmit the data encoded by the encoding unit according to a set wireless transmission rate, and an input-side buffer disposed between the encoding unit and the transmission unit and configured to temporarily store the data encoded by the encoding unit until a transmission timing of the transmission unit.

The output-side device includes a reception unit configured to receive the data wirelessly transmitted from the input-side device, a measurement unit configured to measure quality of a wireless propagation path on the basis of a reception result of the reception unit, a decoding unit configured to decode the data received by the reception unit, an output unit configured to output the data decoded by the decoding unit at an output timing at which delay with respect to a data input from the input-side device becomes constant, and an output-side buffer disposed between the decoding unit and the output unit and configured to temporarily store the data decoded by the decoding unit until the output timing of the output unit.

Further, the wireless communication system of the present invention determines the coding rate and the wireless transmission rate on the basis of the quality of the wireless propagation path measured by the measurement unit and an amount of the data stored in the input-side buffer or an amount of the data stored in the output-side buffer, and the determined coding rate and the determined wireless transmission rate are reflected in settings of the encoding unit and the transmission unit.

As described above, in the present invention, a coding rate and a wireless transmission rate are not determined only with the quality of a wireless propagation path but are determined by considering the amount of data accumulated in a buffer of an input-side device or an output-side device. Accordingly, it is possible to prevent the depletion of data in each buffer, suppress an increase in buffer capacity, and transmit data with low delay.

In the present invention, the “amount of data” is a value that directly or indirectly represents the amount, such as the size or time length, of data. For example, in the case of video data, the number of frames included in the video may be used as the “amount of data.”

As a first configuration example, an output-side device may be configured to determine a coding rate and a wireless transmission rate on the basis of the quality of a wireless propagation path measured by a measurement unit and the amount of data stored in an output-side buffer using the relationship in which the sum of the amount of data stored in an input-side buffer and the amount of data stored in the output-side buffer is constant and to transmit the coding rate and wireless transmission rate to an input-side device so that the coding rate and wireless transmission rate may be reflected in the settings of a coding unit and a transmission unit.

As a second configuration example, an output-side device may be configured to transmit the quality of a wireless propagation path measured by a measurement unit to an input-side device, and the input-side device may be configured to determine a coding rate and a wireless transmission rate on the basis of the quality of the wireless propagation path received from the output-side device and the amount of data stored in an input-side buffer using the relationship in which the sum of the amount of data stored in the input-side buffer and the amount of data stored in an output-side buffer is constant and cause the coding rate and wireless transmission rate to be reflected in the settings of a coding unit and a transmission unit. In this case, the input-side device may be configured to multiplex a signal of the wireless transmission rate with a main line signal (transmission data) and transmit the signals to the output-side device in order to transmit the determined wireless transmission rate to the output-side device.

In the first or second configuration example, “the relationship in which the sum of the amounts of data is constant” may include the relationship in which the sum of the amounts of data is almost constant as well as the relationship in which the sum of the amounts of data is absolutely constant.

### Effect of the Invention

According to the present invention, it is possible to provide a wireless communication system in which it is possible to prevent an increase in buffer capacity and transmit data with low delay while preventing the depletion of data in each buffer.

### BRIEF DESCRIPTION OF THE DRAWINGS

FIG. 1 is a diagram showing a configuration of a mobile station and a base station in a wireless communication system according to a first embodiment of the present invention.

FIG. 2 is a diagram showing a configuration of a mobile station and a base station in a wireless communication system according to a second embodiment of the present invention.

FIGS. 3A and 3B are charts showing simulation results for a wireless transmission rate.

FIGS. 4A and 4B are charts showing simulation results for an output rate of a video encoder.

FIGS. 5A and 5B are charts showing simulation results for operation of each buffer on a mobile station side and a base station side.

### DETAILED DESCRIPTION

An embodiment of the present invention will be described with reference to the drawings.

### First Embodiment

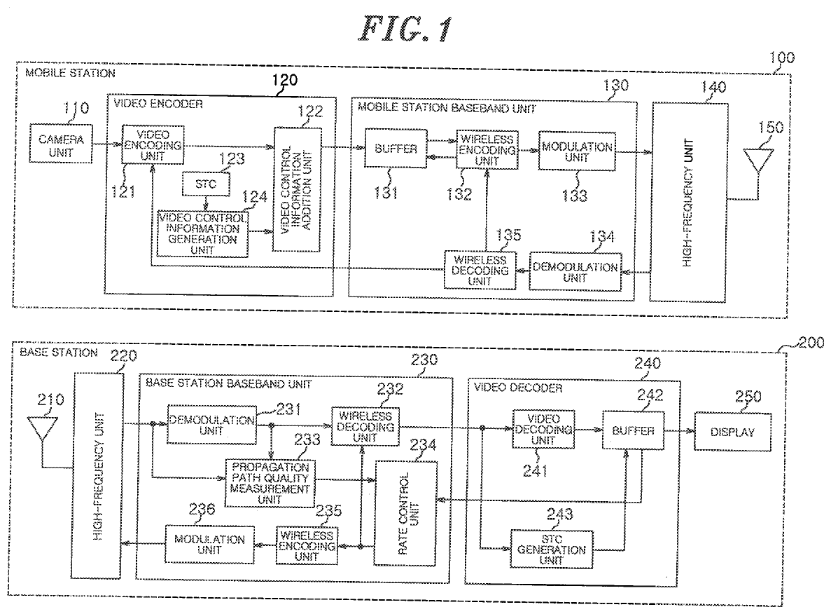

FIG. 1 shows a configuration of a mobile station and a base station in a wireless communication system according to a first embodiment of the present invention. This system is a bidirectional communication system in which wireless signals can be transmitted and received between a mobile station 100 and a base station 200. Further, this system is a variable-rate wireless video transmission system adaptive to a propagation path and is configured to transmit a video captured by the mobile station 100, such as a vehicle with a camera, to the base station 200 present at a predetermined location and also transmit rate control information from the base station 200 to the mobile station 100. In this embodiment, bidirectional communication is performed in a time division duplex (TDD) fashion, but bidirectional communication may be performed in other ways.

The mobile station 100 includes a camera unit 110, a video encoder 120, a mobile station baseband unit 130, a high-frequency unit 140, and an antenna 150. The video encoder 120 includes a video encoding unit 121, a video control information addition unit 122, a system time clock (STC) unit 123, and a video control information generation unit 124. The mobile station baseband unit 130 includes a buffer 131, a wireless encoding unit 132, a modulation unit 133, a demodulation unit 134, and a wireless decoding unit 135.

The base station 200 includes an antenna 210, a high-frequency unit 220, a base station baseband unit 230, a video decoder 240, and a display 250. The base station baseband unit 230 includes a demodulation unit 231, a wireless decoding unit 232, a propagation path quality measurement unit 233, a rate control unit 234, a wireless encoding unit 235, and a modulation unit 236. The video decoder 240 includes a video decoding unit 241, a buffer 242, and an STC generation unit 243.

First, transmission of a video signal from the mobile station 100 to the base station 200 will be described below, and then transmission of rate control information from the base station 200 to the mobile station 100 will be described.

In the mobile station 100, a non-compressed video signal is input from the camera unit 110 to the video encoder 120. In the video encoder 120, the video encoding unit 121 performs video encoding on the video signal input from the camera unit 110 and compresses the data. In this case, the video encoder 120 performs control so that an average value of video coding rates after the compression may become (close to) a video coding rate setting value input from the mobile station baseband unit 130 and outputs the compressed video signal to the video control information addition unit 122. However, since a video coding rate is considerably affected by complexity of the video input to the video encoding unit 121, the average value of video coding rates is not necessarily equal to the video coding rate setting value.

To the video control information addition unit 122, video control information as well as the video signal compressed by the video encoding unit 121 is input. The video control information is generated by the video control information generation unit 124 on the basis of a signal from the STC unit 123 generating an STC, which is a reference time signal, and output to the video control information addition unit 122. The video control information is a program clock reference (PCR), a presentation time stamp (PTS), or the like. The PCR is data used by the video decoder 240 of the base station 200 to generate the STC that is the reference time signal. The PTS is data representing a playback time of the video. The video control information addition unit 122 adds the video control information to the compressed video signal and outputs the compressed video signal to the buffer 131 of the mobile station baseband unit 130 as a transport stream (TS) signal to store the compressed video signal in the buffer 131.

In general, a video coding rate has a longer rate change period and a longer delay compared to a wireless transmission rate. Further, as described above, the video coding rate is considerably affected by the complexity of the video input and thus is not necessarily equal to the video coding rate setting value reported by the mobile station baseband unit 130. Accordingly, it is necessary to compensate for a discrepancy between the wireless transmission rate and the video coding rate using the buffer 131 that accumulates a TS signal from the video encoder 120.

In the mobile station baseband unit 130, the TS signal accumulated in the buffer 131 is read in response to a data request signal from the wireless encoding unit 132 and output to the wireless encoding unit 132. The TS signal in the buffer 131 is removed when output to the wireless encoding unit 132. In other words, the TS signal is temporarily stored in the buffer 131 until the TS signal is output to the wireless encoding unit 132. In addition, when data of the buffer 131 is depleted, the buffer 131 outputs NULL packets to the wireless encoding unit 132 as dummy data, and thus it is not possible to use the maximum wireless transmission capacity.

The wireless encoding unit 132 performs wireless encoding on the input signal (the signal read from the buffer 131) to give redundancy to the input signal and outputs the encoded signal to the modulation unit 133. Subsequently, the wireless encoding unit 132 outputs, to the buffer 131, a request signal for data to be subsequently processed. Further, in the wireless encoding unit 132, a wireless coding rate used in the wireless encoding process is set on the basis of wireless coding rate information reported by the mobile station 100. Details of the wireless coding rate information will be described below.

The modulation unit 133 modulates the signal input from the wireless encoding unit 132 and outputs the modulated signal to the high-frequency unit 140. The high-frequency unit 140 converts the signal input from the modulation unit 133 into a radio frequency (RF) to amplify the signal and outputs the signal to the antenna 150. The antenna 150 transmits the signal input from the high-frequency unit 140 into space.

The signal transmitted from the antenna 150 of the mobile station 100 is received by the antenna 210 of the base station 200 and output to the high-frequency unit 220. The high-frequency unit 220 amplifies the signal received by the antenna 210 to perform frequency conversion on the signal and outputs the signal to the demodulation unit 231 and the propagation path quality measurement unit 233 of the base station baseband unit 230.

The demodulation unit 231 demodulates the signal input from the high-frequency unit 220 and outputs the demodulated signal to the wireless decoding unit 232 and the propagation path quality measurement unit 233. The propagation path quality measurement unit 233 performs a process related to generation of rate control information transmitted from the base station 200 to the mobile station 100 (described below).

Information identical to the wireless coding rate information used by the wireless encoding unit 132 of the mobile station 100 is input from the rate control unit 234 to the wireless decoding unit 232. The wireless decoding unit 232 performs wireless decoding on the signal input from the demodulation unit 231 using the wireless coding rate information input from the rate control unit 234 and outputs the decoded TS signal to the video decoding unit 241 and the STC generation unit 243 of the video decoder 240.

The video decoding unit 241 performs video decoding on the TS signal input from the wireless decoding unit 232 and outputs the decoded video signal to the buffer 242 to store the decoded video signal in the buffer 242. The STC generation unit 243 generates an STC on the basis of the PCR in the TS signal input from the wireless decoding unit 232 and outputs the reference time signal that represents a reference time to the buffer 242.

The buffer 242 outputs data, which has the same PTS as the reference time signal input from the STC generation unit 243 so that a delay time of a playback output from the base station 200 with respect to imaging with the camera (input of video data) at the mobile station 100 becomes constant, to the display 250 and thus causes the display 250 to display the data. The TS signal in the buffer 242 is removed when output on the display 250. In other words, the TS signal is temporarily stored in the buffer 242 until the TS signal is output on the display 250.

Thus far, transmission of a video signal from the mobile station 100 to the base station 200 has been described.

Next, transmission of rate control information from the base station 200 to the mobile station 100 will be described.

Rate control information includes wireless coding rate information for determining a wireless transmission rate RR in the case of transmitting a video signal from the mobile station 100 to the base station 200 and a video coding rate setting value VR in the case of video coding. The rate control information is determined by the rate control unit 234 of the base station baseband unit 230.

A frame number F_{BS} of the video signal accumulated in the buffer 242 of the video decoder 240 and information representing the quality of a wireless propagation path measured by the propagation path quality measurement unit 233 are input to the rate control unit 234. The propagation path quality measurement unit 233 calculates a signal to noise ratio (SNR) and a carrier to noise ratio (CNR) of the received signal, a modulation error ratio (MER), a unique value that is an indicator in the case of multiple input multiple output (MIMO) transmission, etc. to measure the quality of the wireless propagation path and outputs the quality information of the wireless propagation path to the rate control unit 234. The rate control unit 234 determines the wireless transmission rate RR and the video coding rate setting value VR on the basis of the input information and outputs the rate control information including the wireless coding rate information for realizing the wireless transmission rate RR and the video coding rate setting value VR to the wireless encoding unit 235. A detailed method of determining each rate will be described below.

The wireless encoding unit 235 gives redundancy to the rate control information input from the rate control unit 234 by performing wireless encoding on the rate control information in order to report the rate control information to the mobile station 100 without error and outputs the encoded signal to the modulation unit 236. The modulation unit 236 modulates the signal input from the wireless encoding unit 235 and outputs the modulated signal to the high-frequency unit 220. The high-frequency unit 220 converts the signal input from the modulation unit 236 into an RF to amplify the signal and outputs the signal to the antenna 210. The antenna 210 transmits the signal input from the high-frequency unit 220 into space.

The signal transmitted from the antenna 210 of the base station 200 is received by the antenna 150 of the mobile station 100 and output to the high-frequency unit 140. The high-frequency unit 140 amplifies the signal received by the antenna 150 to perform frequency conversion on the signal and outputs the signal to the demodulation unit 134 of the mobile station baseband unit 130.

The demodulation unit 134 demodulates the signal input from the high-frequency unit 140 and outputs the demodulated signal to the wireless decoding unit 135. The wireless decoding unit 135 performs wireless decoding on the signal input from the demodulation unit 134 and decodes the rate control information including the wireless coding rate information and the video coding rate setting value VR. The wireless decoding unit 135 outputs the wireless coding rate information to the wireless encoding unit 132 and outputs the video coding rate setting value VR to the video encoding unit 121 of the video encoder 120.

As described above, the wireless encoding unit 132 performs wireless encoding on a main line signal using a wireless coding rate that is set on the basis of the wireless coding rate information, and the video encoding unit 121 performs video encoding so that an average value of video coding rates may become the video coding rate setting value VR.

In this way, it is possible to transmit a video signal using the wireless transmission rate RR and the video coding rate setting value VR in which the quality of a wireless propagation path between the mobile station 100 and the base station 200 and the number of frames of the video signal accumulated in the buffer 242 of the base station 200 are taken into consideration.

Next, a method for the rate control unit 234 of the base station 200 to determine the wireless transmission rate RR and the video coding rate setting value VR is described. The wireless transmission rate RR may be calculated by Equation 1 below:

RR=R_{RAW}−M+G_{BS}·F_{BS_UD}·G_{MS}·F_{MS_UD} Equation 1

where R_{raw} is a maximum transmission rate (assumed value) without error and calculated on the basis of the quality of a wireless propagation path, M is a margin, G_{BS} is a gain multiplied by F_{BS_UD}, G_{MS} is a gain multiplied by F_{MS_UD}, and all of these are set in advance.

Further, F_{BS_UD} is a value calculated by Equation 2-1 or Equation 2-2 below:

F_{BS_UD}=THR_{BS}−F_{BS} (when 0≤THR_{BS}−F_{BS}) Equation 2-1

F_{BS_UD}=0 (when 0>THR_{BS}−F_{BS}) Equation 2-2

where THR_{BS} is a threshold value of the number of remaining frames for preventing the depletion of data in the buffer 242 of the video decoder 240 and is set in advance, and F_{BS} is the number of frames accumulated in the buffer 242 of the video decoder 240.

Further, F_{MS_UD} is a value calculated by Equation 3-1 or Equation 3-2 below:

F_{MS_UD}=THR_{MS}−F_{MS} (when 0≤THR_{MS}−F_{MS}) Equation 3-1

F_{MS_UD}=0 (when 0>THR_{MS}−F_{MS}) Equation 3-2

where THR_{MS} is a threshold value of the number of remaining frames for preventing the depletion of data in the buffer 131 of the mobile station baseband unit 130 and is set in advance, and F_{MS} is the number of frames accumulated in the buffer 131 of the mobile station baseband unit 130.

As shown in the above equations, the rate control unit 234 corrects a value obtained by adding a predetermined margin to the maximum rate, which is calculated on the basis of the quality of a wireless propagation path, on the basis of the accumulated frame number F_{MS} of the buffer 131 of the mobile station baseband unit 130 and the accumulated frame number F_{BS} of the buffer 242 of the video decoder 240 and calculates the wireless transmission rate RR. Specifically, when the accumulated frame number F_{BS} of the buffer 242 of the video decoder 240 is smaller than the threshold value THR_{BS}, a correction is made to increase the wireless transmission rate RR in order to prevent the depletion of data in the buffer 242. On the other hand, when the accumulated frame number F_{MS} of the buffer 131 of the mobile station baseband unit 130 is smaller than the threshold value THR_{MS}, a correction is made to increase the wireless transmission rate RR in order to prevent the depletion of data in the buffer 131.

However, in the configuration of the first embodiment (FIG. 1), the rate control unit 234 cannot directly observe the accumulated frame number F_{MS} of the buffer 131 of the mobile station baseband unit 130. Accordingly, the rate control unit 234 calculates the accumulated frame number F_{MS} of the buffer 131 of the mobile station baseband unit 130 using a relationship described below.

In the base station 200, a video signal stored in the buffer 242 is output and displayed on the display 250 according to an STC signal generated by the STC generation unit 243 of the video decoder 240. For this reason, a delayed frame number F_{ALL} from imaging at the mobile station 100 to displaying at the base station 200 becomes constant at all times. Accordingly, a relational expression is obtained as shown in Equation 4 below:

F_{ALL}=F_{MS}+F_{BS} Equation 4.

Since the delayed frame number F_{ALL} from imaging to displaying is set in advance during system operation, the accumulated frame number F_{MB} of the buffer 131 of the mobile station baseband unit 130 may be calculated by Equation 5 below when the accumulated frame number F_{BS} of the buffer 242 of the video decoder 240 is obtained:

F_{MS}=F_{ALL}−F_{BS} Equation 5.

Therefore, Equation 3-1 and Equation 3-2 may be represented by Equation 6-1 and Equation 6-2 below:

F_{MS_UD}=THR_{MS}−(F_{ALL}−F_{BS}) (when 0≤THR_{MS}−(F_{ALL}−F_{BS})) Equation 6-1

F_{MS_UD}=0 (when 0>THR_{MS}−(F_{ALL}−F_{BS})) Equation 6-2.

Further, the video coding rate setting value VR may be calculated by Equation 7 below:

VR=R_{RAW}−M+G_{VR}·(F_{BS}−S) Equation 7

where S is a control target value for the number of frames accumulated in the buffer 242 of the video decoder 240, and G_{VR} is a gain multiplied by (F_{BS}-S). These values are set in advance.

In other words, the rate control unit 234 corrects the value obtained by adding the predetermined margin to the maximum rate, which is calculated on the basis of the quality of the wireless propagation path, on the basis of the accumulated frame number F_{BS} of the buffer 242 of the video decoder 240 and calculates the video coding rate setting value VR. Specifically, the video coding rate setting value VR is corrected so that the accumulated frame number F_{BS} of the buffer 242 of the video decoder 240 may become close to the control target value S.

As described above, when the wireless transmission rate RR is adjusted on the basis of the accumulated frame number F_{MS} of the buffer 131 of the mobile station baseband unit 130 and the accumulated frame number F_{BS} of the buffer 242 of the video decoder 240, the following two effects can be obtained.

For the first effect, when the accumulated frame number F_{BS} of the buffer 242 of the video decoder 240 is reduced and the probability of video stuttering due to the depletion of data increases, the wireless transmission rate RR is increased by reducing a margin of wireless transmission so that the depletion of data can be prevented. For the second effect, when the accumulated frame number F_{MS} of the buffer 131 of the mobile station baseband unit 130 is reduced and data depletion is likely to occur, NULL packets are prevented from being sent as dummy data by reducing the wireless transmission rate RR so that degradation of transmission efficiency can be prevented.

The first effect can be achieved by directly monitoring and controlling the accumulated frame number F_{BS} of the buffer 242 of the video decoder 240, and the second effect can be achieved by calculating the accumulated frame number F_{MS} of the buffer 131 of the mobile station baseband unit 130 from the accumulated frame number F_{BS} of the buffer 242 of the video decoder 240 on the basis of the relationship in which video delay is constant and performing control.

Further, the video coding rate setting value VR is adjusted on the basis of the accumulated frame number F_{BS} of the buffer 242 of the video decoder 240, and thus it is possible to prevent video stuttering resulting from the depletion of data in the buffer 242 caused by the delay of a change in video rate with respect to a change in the wireless transmission rate RR.

### Second Embodiment

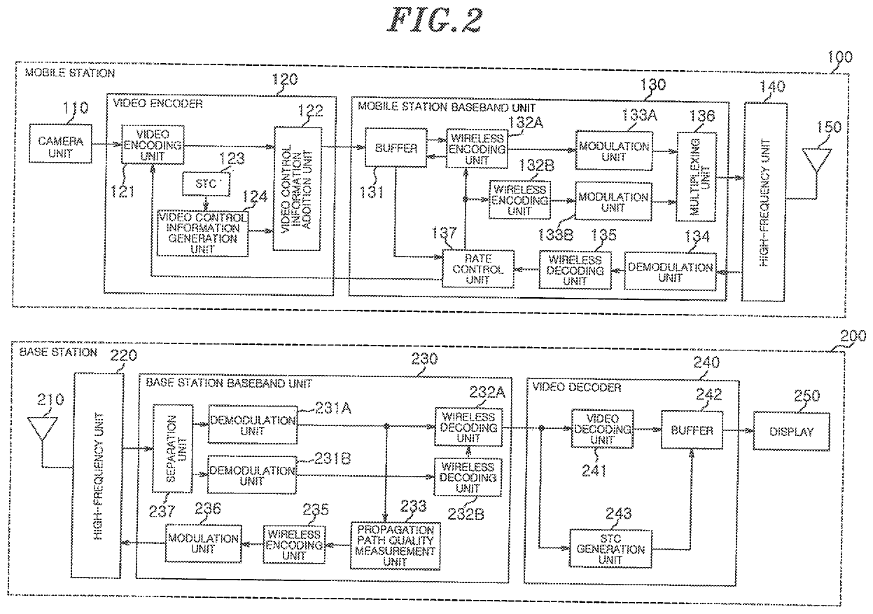

FIG. 2 shows a configuration of a mobile station and a base station in a wireless communication system according to a second embodiment of the present invention. In the first embodiment, the base station baseband unit 230 needs to provide an interface for observing the accumulated frame number F_{BS} of the buffer 242 of the video decoder 240. However, in the second embodiment, such an interface is unnecessary. Since a configuration of the second embodiment is similar to that of the first embodiment, and thus the difference therebetween will only be described.

In the second embodiment, a mobile station baseband unit 130 includes a buffer 131, wireless encoding units 132A and 132B, modulation units 133A and 133B, a multiplexing unit 136, a demodulation unit 134, a wireless decoding unit 135, and a rate control unit 137. Further, a base station baseband unit 230 includes a separation unit 237, demodulation units 231A and 231B, wireless decoding units 232A and 232B, a propagation path quality measurement unit 233, a wireless encoding unit 235, and a modulation unit 236.

The following three differences are the main differences between the first embodiment and the second embodiment.

First, there is no means of reporting an accumulated frame number F_{BS} of a buffer 242 of a video decoder 240 to the base station baseband unit 230.

Second, the base station baseband unit 230 does not perform rate control (does not have the rate control unit 234) and reports quality information of a wireless propagation path to the mobile station 100, and the rate control unit 137 installed in the mobile station baseband unit 130 performs rate control using the quality information of the wireless propagation path reported by the base station baseband unit 230 and an accumulated frame number F_{MS} of the buffer 131 of the mobile station baseband unit 130.

Third, a means is added to share a wireless coding rate corresponding to a wireless transmission rate RR calculated by the rate control unit 137 of the mobile station baseband unit 130 with the base station baseband unit 230.

First, a report of the quality information of the wireless propagation path to the mobile station 100 will be described. The quality information of the wireless propagation path calculated by the propagation path quality measurement unit 233 is input to the wireless encoding unit 235 unlike in the first embodiment and transmitted to the wireless decoding unit 135 of the mobile station baseband unit 130. A transmission process from the wireless encoding unit 235 to the wireless decoding unit 135 is the same as that described in the first embodiment, and thus the description thereof will be omitted. The quality information of the wireless propagation path decoded by the wireless decoding unit 135 is input to the rate control unit 137.

To the rate control unit 137, an accumulated frame number F_{MS} of the buffer 131 of the mobile station baseband unit 130 is input as well. As in the first embodiment, the rate control unit 137 calculates the wireless transmission rate RR and a video coding rate setting value VR on the basis of the quality information of the wireless propagation path and the accumulated frame number F_{MS} according to Equation 1 and Equation 7.

Here, F_{BS_UD} and F_{MS_UD} are calculated by Equation 2-1 or Equation 2-2 and Equation 3-1 or Equation 3-2 of the first embodiment. However, in the second embodiment, it is possible to directly observe the accumulated frame number F_{MS} of the buffer 131 of the mobile station baseband unit 130, and it is not possible to directly observe the accumulated frame number F_{BS} of the buffer 242 of the video decoder 240.

As described in the first embodiment, a delayed frame number F_{ALL} from imaging at the mobile station 100 to displaying at the base station 200 is constant at all times, and thus the relational expression of Equation 4 holds. From this, it is possible to know that the accumulated frame number F_{BS} of the buffer 242 of the video decoder 240 can be calculated when the accumulated frame number F_{MS} of the buffer 131 of the mobile station baseband unit 130 is obtained.

Accordingly, Equation 2-1 and Equation 2-2 may be represented by Equation 8-1 and Equation 8-2 below:

F_{BS_UD}=THR_{BS}−(F_{ALL}−F_{MS}) (when 0≤THR_{BS}−(F_{ALL}−F_{MS}) Equation 8-1

F_{BS_UD}=0 (when 0>THR_{BS}−(F_{ALL}−F_{MS})) Equation 8-2.

Further, Equation 7 may be represented by Equation 9 below:

VR=R_{RAW}−M+G_{VR}·(F_{ALL}−F_{BS}−S) Equation 9.

When the wireless transmission rate RR and the video coding rate setting value VR are calculated by the above equations, the rate control unit 137 outputs the video coding rate setting value VR to the video encoding unit 120 of the video encoder 121 and outputs wireless coding rate information for realizing the wireless transmission rate RR to the wireless encoding units 132A and 132B. Details of a process of the wireless encoding unit 132A and the modulation unit 133A are the same as those of the wireless encoding unit 132 and the modulation unit 133 in the first embodiment, and thus description thereof will be omitted.

The wireless encoding unit 132B, the modulation unit 133B, and the multiplexing unit 136 are functional units added to report wireless coding rate information to the base station baseband unit 230. The wireless encoding unit 132B performs wireless encoding on the wireless coding rate information input from the rate control unit 137 and outputs the signal after the encoding to the modulation unit 133B. The modulation unit 133B modulates the signal input from the wireless encoding unit 132B and the signal after the modulation to the multiplexing unit 136. A signal obtained by modulating a video signal is also input from the modulation unit 133A to the multiplexing unit 136, and the multiplexing unit 136 multiplexes and outputs the signals to a high-frequency unit 140.

The signals input to the high-frequency unit 140 are transmitted to the base station 200 through the same procedure as that of the first embodiment and output to the separation unit 237 of the base station baseband unit 230. The separation unit 237 separates the video signal and the wireless coding rate information signal from the input signal (received signal), outputs the video signal to the demodulation unit 231A, and outputs the wireless coding rate information signal to the demodulation unit 231B.

Details of a process of the demodulation unit 231A are the same as those of the demodulation unit 231 in the first embodiment, and thus description thereof will be omitted. The demodulation unit 231B demodulates the signal input from the separation unit 237 and outputs the demodulated signal to the wireless decoding unit 232B. The wireless decoding unit 232B performs wireless decoding on the signal input from the demodulation unit 231B and outputs the decoded wireless coding rate information to the wireless decoding unit 232A. The wireless decoding unit 232A performs wireless decoding on the signal input from the demodulation unit 231A using the wireless coding rate information input from the wireless decoding unit 232B.

Through the above process, in the second embodiment, the mobile station 100 can perform rate control and report wireless coding rate information for realizing the wireless transmission rate RR to the base station 200. Accordingly, in the second embodiment, it is possible to implement the same function as in the first embodiment.

In the first embodiment, it is acceptable to only report rate control information including a wireless transmission rate RR calculated in the base station 200 and a video rate setting value VR to the mobile station 100. However, the buffer 242 installed in the base station 200 needs to be disposed in the video decoder 240 due to a role thereof. Accordingly, an interface for reporting the accumulated frame number F_{BS} of the buffer 242 to the base station baseband unit 230 in real time is necessary between the base station baseband unit 230 and the video decoder 240.

Meanwhile, in the second embodiment, the interface is unnecessary, but there is a need for a means of reporting the quality information of a wireless propagation path from the base station 200 to the mobile station 100 and also reporting wireless coding rate information based on the wireless transmission rate RR calculated by the mobile station 100 from the mobile station 100 to the base station 200.

In the above-described two embodiments, to make a wireless transmission error tolerance variable, an error correction coding rate is made variable. However, it is possible to make a wireless transmission error tolerance variable in other ways such as making a modulation level variable.

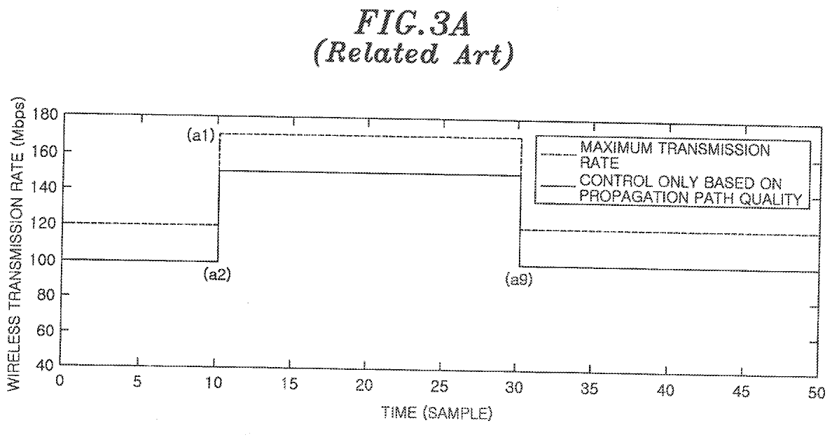

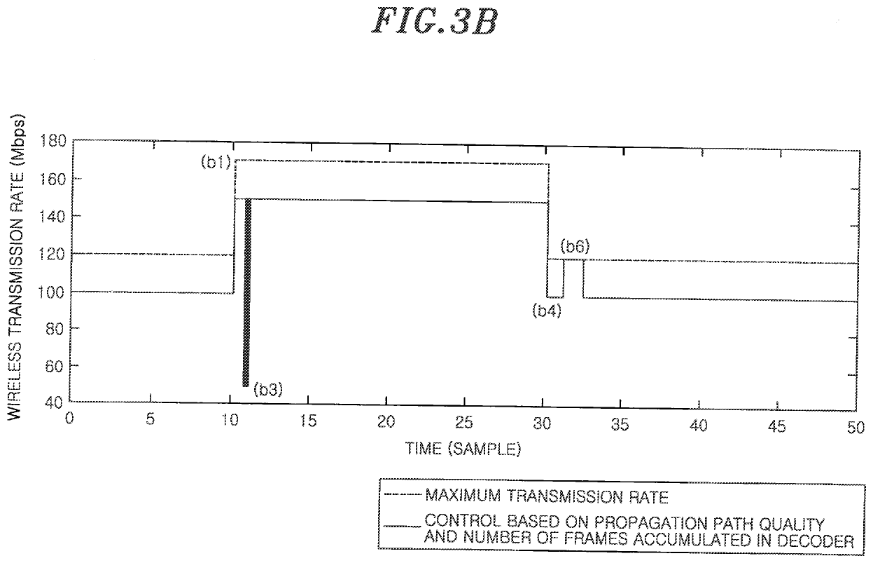

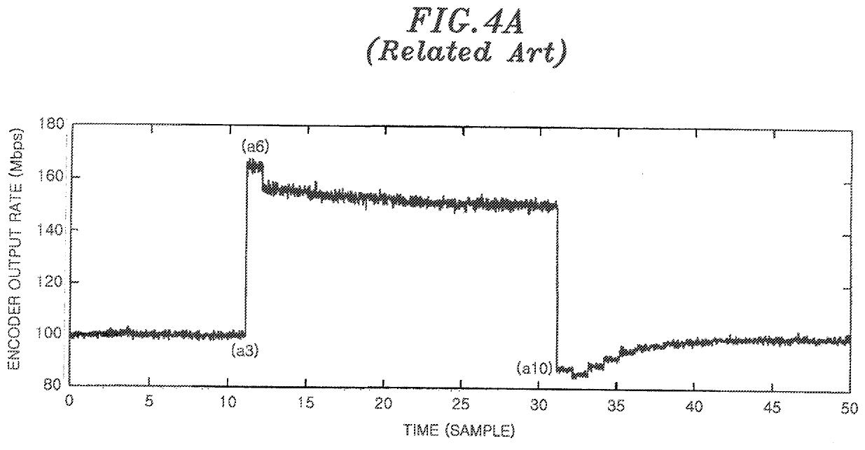

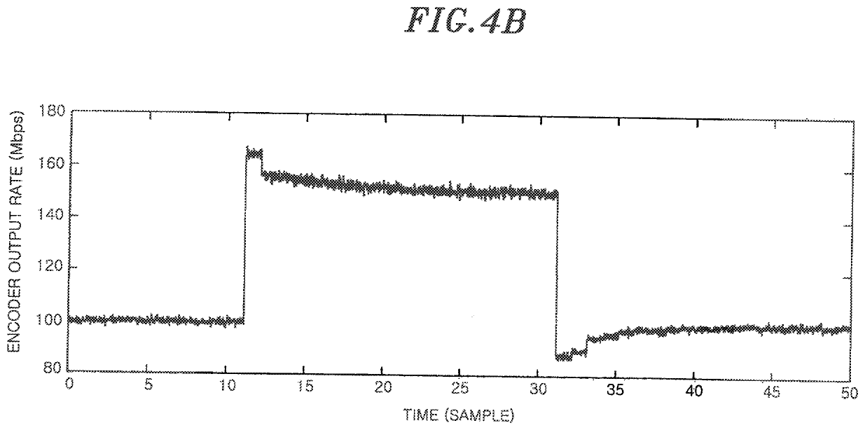

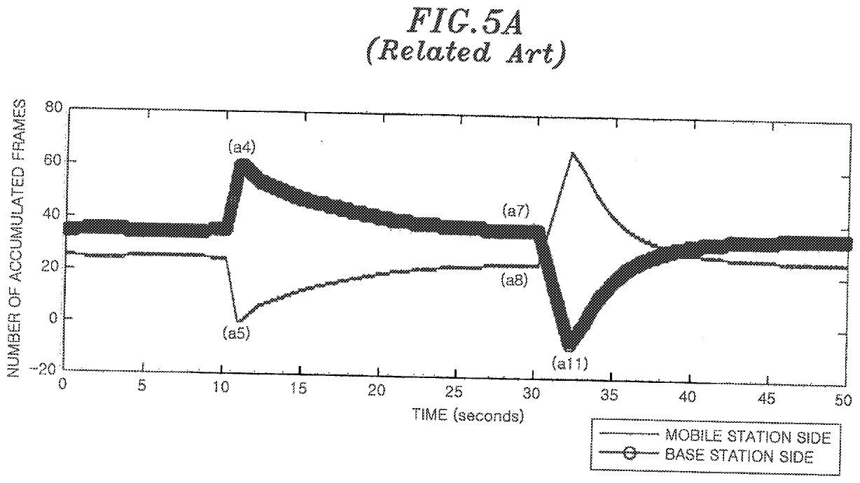

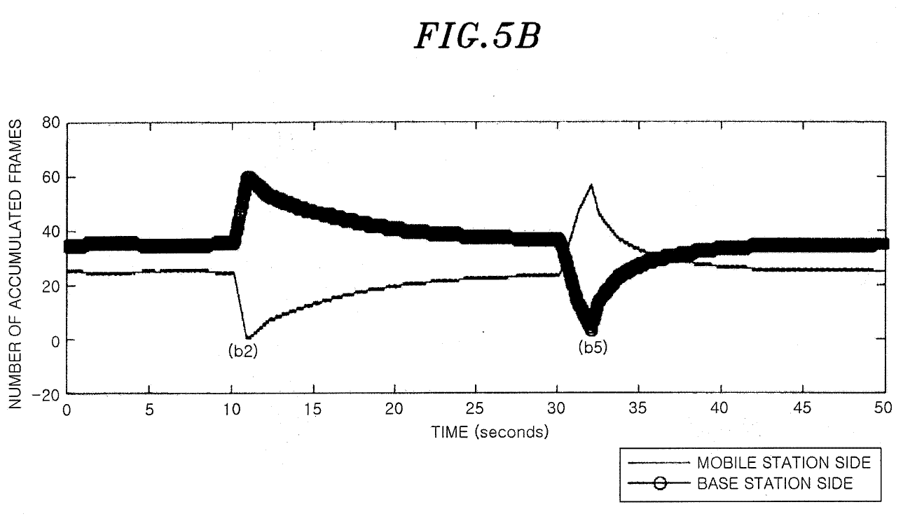

Next, simulation results of the above-described rate control will be described with reference to FIGS. 3A to 5B. Here, a simulation is carried out for a case in which the quality of a wireless propagation path is drastically improved from a poor level and then drastically degraded. FIGS. 3A and 3B show a wireless transmission rate, FIGS. 4A and 4B show an output rate (video coding rate) of a video encoder, and FIGS. 5A and 5B show operation of each buffer on a mobile station side and a base station side. The output rate of a video encoder represents the quality of the wireless propagation path that reflects a control delay. In each of FIGS. 3A to 5B, FIGS. 3A, 4A and 5A correspond to a case of performing rate control on the basis of only the quality of the wireless propagation path (i.e., a conventional method), and FIGS. 3B, 4B and 5B correspond to a case of performing rate control on the basis of the quality of the wireless propagation path and an accumulated frame number of a decoder (i.e., the method proposed by the present invention).

First, the simulation results of the case of performing rate control on the basis of only the quality of the wireless propagation path will be described.

When the quality of the wireless propagation path is drastically improved from a poor level (a1), a wireless transmission rate is increased by rapidly following the change in the quality of the wireless propagation path (a2), but the output rate of the video encoder is changed with delay and thus is not increased for a while (a3). During the delay, the number of frames accumulated in a buffer of the base station side reaches a preset delay frame number of the overall system (in this example, 60 frames) (a4), and an accumulated frame number of a buffer of the mobile station side becomes zero (a5) so that NULL packets are sent.

Then, when the output rate of the video encoder is increased according to the quality of the wireless propagation path (a6), the accumulated frame number in the buffer of the base station side gradually returns to a control target level (a7), and the accumulated frame number in the buffer of the mobile station also gradually returns to a control target level (a8).

Subsequently, when the quality of the wireless propagation path is drastically degraded, a reduction in the output rate of the video encoder is delayed (a10) with respect to a drastic reduction in the wireless transmission rate (a9). At this time, the number of frames that can be transmitted per unit time is temporarily reduced, and accumulated frames in the buffer of the mobile station side are depleted (a11) such that the video stutters.

Next, the simulation results of the case of performing rate control on the basis of the quality of the wireless propagation path and the accumulated frame number of the decoder will be described.

When the quality of the wireless propagation path is drastically improved from a poor level (b1) and accumulated frames in the buffer of the mobile station side are reduced and likely to be depleted (b2), a wireless transmission rate is reduced (b3) so that NULL packets are controlled not to be sent. On the other hand, when the quality of the wireless propagation path is drastically degraded (b4), the number of frames in the buffer of the base station side is reduced (b5). However, before frames in the buffer of the mobile station side are reduced and depleted, a wireless transmission margin is reduced, and a wireless coding rate is increased so that the wireless transmission rate is increased (b6). Consequently, it is possible to prevent the depletion of frames in the buffer of the base station side.

As described above, the wireless communication system according to each embodiment includes the mobile station 100 that encodes video data input from the camera 110 and wirelessly transmits the encoded video data and the base station 200 that decodes the data received from the mobile station 100 and outputs the decoded data to the display 250. The mobile station 100 is an example of an input-side device according to the present invention, and the base station 200 is an example of an output-side device according to the present invention.

The mobile station 100 includes the video encoding unit 121 that encodes the input video data according to a set video coding rate, a transmission block (the wireless encoding unit 132, the modulation unit 133, the high-frequency unit 140, and the antenna 150) that wirelessly transmits the video data encoded by the video encoding unit 121 according to a set wireless transmission rate, and the buffer 131 that is disposed between the video encoding unit 121 and the transmission block and temporarily store the video data encoded by the video encoding unit 121 until a transmission timing of the transmission block.

The base station 200 includes a reception block (the antenna 210, the high-frequency unit 220, the demodulation unit 231, and the wireless decoding unit 232) that receives the video data wirelessly transmitted from the mobile station 100, the propagation path quality measurement unit 233 that measures the quality of a wireless propagation path on the basis of a reception result of the reception block, the video decoding unit 241 that decodes the video data received by the reception block, the display 250 that outputs and displays the video data decoded by the video decoding unit 241 at a timing at which delay with respect to the video data input from the mobile station 100 becomes constant, and the buffer 242 that is disposed between the video decoding unit 241 and the display 250 and temporarily stores the video data decoded by the video decoding unit 241 until an output and display timing of the display 250.

In the first embodiment, the base station 200 is configured to determine a video coding rate and a wireless transmission rate on the basis of the quality of a wireless propagation path measured by the propagation path quality measurement unit 233 and the amount of data stored in the buffer 241 thereof using the relationship in which the sum of the amount of data stored in the buffer 131 of the mobile station 100 and the amount of data stored in the buffer 241 of the base station 200 is constant, and the base station 200 is further configured to transmit the video coding rate and wireless transmission rate to the mobile station 100 so that the video coding rate and wireless transmission rate may be reflected in the settings of the video encoding unit 121 and the wireless encoding unit 132.

In the second embodiment, the base station 200 is configured to transmit the quality of a wireless propagation path measured by the propagation path quality measurement unit 233 to the mobile station 100, and the mobile station 100 is configured to determine a video coding rate and a wireless transmission rate on the basis of the quality of the wireless propagation path received from the base station 200 and the amount of data stored in the buffer 131 thereof using the relationship in which the sum of the amount of data stored in the buffer 131 of the mobile station 100 and the amount of data stored in the buffer 241 of the base station 200 is constant, and the base station 200 is further configured to cause the video coding rate and wireless transmission rate to be reflected in the settings of the video encoding unit 121 and the wireless encoding unit 132.

As described above, in both the first embodiment and the second embodiment, a video coding rate and a wireless transmission rate calculated on the basis of the quality of a wireless propagation path are adjusted in consideration of the amount of data accumulated in the buffer 131 of the mobile station 100 or the amount of data accumulated in the buffer 241 of the base station 200. Specifically, for example, when the amount of data accumulated in the buffer 241 of the base station 200 becomes close to zero, the wireless transmission rate calculated on the basis of the quality of the wireless propagation path is adjusted to increase. On the other hand, when the amount of data accumulated in the buffer 131 of the mobile station 100 becomes close to zero, the wireless transmission rate calculated on the basis of the quality of the wireless propagation path is adjusted to decrease. However, the adjustment is made not to set a wireless transmission rate at which a wireless transmission error clearly occurs.

Through such controls, it is possible to prevent an increase in buffer capacity and transmit data with low delay while preventing the depletion of data in the buffer 131 of the mobile station 100 or the buffer 241 of the base station 200. In this way, it is possible to prevent video stuttering caused by the depletion of data in each buffer and degradation of transmission efficiency caused by transmission of NULL packets. Further, the amount of data (the number of frames) accumulated in each buffer can be set to the minimum, and video transmission can be realized with low delay.

Although the present invention has been described in detail above with reference to embodiments, the present invention is not limited to the wireless communication systems set forth herein and can be extensively applied to wireless communication systems other than the above.

For example, in each of the embodiments, a mobile station integrally includes a camera that is an input unit of video data, and a base station integrally includes a display that is an output unit of video data. However, such an input unit or output unit may be installed in a device separate from the mobile station or base station.

Further, in each of the embodiments, video data transmission is performed in an uplink direction from a mobile station to a base station, but the present invention can also be applied to video data transmission in a downlink direction from a base station to a mobile station.

The present invention may be applied to a wireless communication system that transmits audio data instead of or together with video data. In other words, for example, in a wireless communication system, in which a mobile station having a microphone for collecting sound encodes audio data input from the microphone and wirelessly transmits the audio data to a base station and the base station plays back and output the audio data at a timing at which delay with respect to the audio data input from the mobile station is constant, an audio coding rate and a wireless transmission rate calculated on the basis of the quality of a wireless propagation path may be adjusted in consideration of the amount of data accumulated in a buffer of the mobile station or a buffer of the base station. Further, the present invention may be applied to a wireless communication system in which data other than video data or audio data is encoded and transmitted.

The present invention may be understood as a transmitting station (input-side device) or a receiving station (output-side device) included in the wireless communication system.

Further, the present invention may be provided as, for example, a method or way of performing a process according to the present invention, a program for implementing the method or way, a storage medium for storing the program, and the like.

This application claims priority to Japanese Patent Application No. 2018-175547, filed on Sep. 20, 2018, the entire contents of which are incorporated herein by reference.

### INDUSTRIAL APPLICABILITY

The present invention can be used in a wireless communication system including an input-side device that encodes input data and wirelessly transmits the data and an output-side device that decodes the data received from the input-side device and outputs the data.

### EXPLANATION OF REFERENCE NUMERALS

100: mobile station
110: camera unit
120: video encoder
121: video encoding unit
122: video control information addition unit
123: STC unit
124: video control information generation unit
130: mobile station baseband unit
131: buffer
132, 132A, 132B: wireless encoding unit
133, 133A, 133B: modulation unit
134: demodulation unit
135: wireless decoding unit
136: multiplexing unit
137: rate control unit
140: high-frequency unit
150: antenna
200: base station
210: antenna
220: high-frequency unit
230: base station baseband unit
231, 231A, 231B: demodulation unit
232, 232A, 232B: wireless decoding unit
233: propagation path quality measurement unit
234: rate control unit
235: wireless encoding unit
236: modulation unit
237: separation unit
240: video decoder
241: video decoding unit
242: buffer
243: STC generation unit

1. (canceled)

2. A wireless communication system comprising:
an input-side device configured to encode data input thereto and wirelessly transmit the data; and
an output-side device configured to decode the data received from the input-side device and output the data,
wherein the input-side device includes:
an encoding unit configured to encode data input thereto according to a set coding rate;
a transmission unit configured to wirelessly transmit the data encoded by the encoding unit according to a set wireless transmission rate; and
an input-side buffer disposed between the encoding unit and the transmission unit and configured to temporarily store the data encoded by the encoding unit until a transmission timing of the transmission unit,
wherein the output-side device includes:
a reception unit configured to receive the data wirelessly transmitted from the input-side device;
a measurement unit configured to measure quality of a wireless propagation path on the basis of a reception result of the reception unit;
a decoding unit configured to decode the data received by the reception unit;
an output unit configured to output the data decoded by the decoding unit at an output timing at which delay with respect to a data input from the input-side device becomes constant; and
an output-side buffer disposed between the decoding unit and the output unit and configured to temporarily store the data decoded by the decoding unit until the output timing of the output unit,
wherein the coding rate and the wireless transmission rate are determined on the basis of the quality of the wireless propagation path measured by the measurement unit and an amount of the data stored in the input-side buffer or an amount of the data stored in the output-side buffer, and the determined coding rate and the determined wireless transmission rate are reflected in settings of the encoding unit and the transmission unit, and
wherein the output-side device determines the coding rate and the wireless transmission rate on the basis of the quality of the wireless propagation path measured by the measurement unit and the amount of the data stored in the output-side buffer using a relationship in which the sum of the amount of the data stored in the input-side buffer and the amount of the data stored in the output-side buffer is constant, and the output-side device transmits the determined coding rate and the determined wireless transmission rate to the input-side device, and reflects the determined coding rate and the determined wireless transmission rate in the settings of the encoding unit and the transmission unit.

3. A wireless communication system comprising:
an input-side device configured to encode data input thereto and wirelessly transmit the data; and
an output-side device configured to decode the data received from the input-side device and output the data,
wherein the input-side device includes:
an encoding unit configured to encode data input thereto according to a set coding rate;
a transmission unit configured to wirelessly transmit the data encoded by the encoding unit according to a set wireless transmission rate; and
an input-side buffer disposed between the encoding unit and the transmission unit and configured to temporarily store the data encoded by the encoding unit until a transmission timing of the transmission unit,
wherein the output-side device includes:
a reception unit configured to receive the data wirelessly transmitted from the input-side device;
a measurement unit configured to measure quality of a wireless propagation path on the basis of a reception result of the reception unit;
a decoding unit configured to decode the data received by the reception unit;
an output unit configured to output the data decoded by the decoding unit at an output timing at which delay with respect to a data input from the input-side device becomes constant; and
an output-side buffer disposed between the decoding unit and the output unit and configured to temporarily store the data decoded by the decoding unit until the output timing of the output unit,
wherein the coding rate and the wireless transmission rate are determined on the basis of the quality of the wireless propagation path measured by the measurement unit and an amount of the data stored in the input-side buffer or an amount of the data stored in the output-side buffer, and the determined coding rate and the determined wireless transmission rate are reflected in settings of the encoding unit and the transmission unit, and
wherein the output-side device transmits the quality of the wireless propagation path measured by the measurement unit to the input-side device, and
the input-side device determines the coding rate and the wireless transmission rate on the basis of the quality of the wireless propagation path received from the output-side device and the amount of the data stored in the input-side buffer using a relationship in which the sum of the amount of the data stored in the input-side buffer and the amount of the data stored in the output-side buffer is constant, and the input-side device reflects the determined coding rate and the determined wireless transmission rate in the settings of the encoding unit and the transmission unit.

4. (canceled)

5. An input-side device that wirelessly communicates with an output-side device including a reception unit configured to receive wirelessly transmitted data, a measurement unit configured to measure quality of a wireless propagation path on the basis of a reception result of the reception unit, a decoding unit configured to decode the data received by the reception unit, an output unit configured to output the data decoded by the decoding unit at an output timing at which delay with respect to a data input from the input-side device becomes constant, and an output-side buffer disposed between the decoding unit and the output unit and configured to temporarily store the data decoded by the decoding unit until the output timing of the output unit, the input-side device comprising:
an encoding unit configured to encode data input thereto according to a set coding rate;
a transmission unit configured to wirelessly transmit the data encoded by the encoding unit according to a set wireless transmission rate; and
an input-side buffer disposed between the encoding unit and the transmission unit and configured to temporarily store the data encoded by the encoding unit until a transmission timing of the transmission unit,
wherein the quality of the wireless propagation path measured by the measurement unit is received from the output-side device, and the coding rate and the wireless transmission rate are determined on the basis of the quality of the wireless propagation path received from the output-side device and an amount of the data stored in the input-side buffer using a relationship in which the sum of the amount of the data stored in the input-side buffer and an amount of the data stored in the output-side buffer is constant, and the determined coding rate and the determined wireless transmission rate are reflected in settings of the encoding unit and the transmission unit.

6. (canceled)

7. (canceled)
